(19) United States
(12) Patent Application Publication
(10) Pub. No.: US 2007/0293056 A1
(43) Pub. Date: Dec. 20, 2007

(54) Surface Modification Method for Solid Sample, Impurity Activation Method, and Method for Manufacturing Semiconductor Device

(75) Inventors: Yuichi Setsuhara, Mino-shi (JP); Masaki Hashida, Osaka-shi (JP); Masayuki Fujita, Mino-shi (JP)

Correspondence Address: OLIFF & BERRIDGE, PLC, P.O. BOX 320850, ALEXANDRIA, VA, 22320-4850, US

(73) Assignee: EMD CORPORATION, KYOTO-SHI (JP)

(21) Appl. No.: 11/587,815

(22) PCT Filed: Apr. 28, 2005
(86) PCT No.: PCT/JP05/08154

§ 371 Date: Oct. 27, 2006

(30) Foreign Application Priority Data
Apr. 28, 2004 (JP) 2004-13400

(51) Int. Cl. H01L 21/265; H01L 21/268

(52) U.S. Cl. 438/795; 438/519; 257/E21.347; 257/E21.334

(57) ABSTRACT

The present invention intends to provide a method for manufacturing a semiconductor device in which source/drain extension regions having a uniform depth are created with high reproducibility. This objective is achieved by the following method: A gate electrode 24 is formed on a semiconductor substrate 21 via a gate insulator 23. The portion of the semiconductor substrate 21 other than the gate electrode 24 is irradiated with an ultra-short pulsed laser light having a pulse width within a range from 10 to 1000 femtoseconds in order to create an amorphous layer 26a. Then, recesses 27 are created in the semiconductor substrate 21 by selectively etching the amorphous layer 26a. The recesses 27 are filled with semiconductor layers 28 whose impurity concentration is higher than that of the semiconductor substrate 21, and the source/drain extension regions 31 are created there. Within the region other than the gate electrode 24 and the source/drain extension regions 31, Deep diffusion layers 30 deeper than the source/drain extension regions 31 are created.

### TECHNICAL FIELD

The present invention relates to a surface modification method for modifying only a surface region of a silicon substrate or other solid samples, an impurity activation method for activating an impurity layer created in a semiconductor substrate, and a method for manufacturing a semiconductor device.

### BACKGROUND ART

In the advent of multimedia age using information and communication technologies, there is a large amount of information to be processed at high speeds with more sophisticated functional devices. This situation has caused the ongoing miniaturization and high-density integration of metal-oxide-semiconductor (MOS) transistors used in ultra-large scale integrated circuits (ULSI).

The miniaturization of the MOS transistors inevitably causes the short channel effect. To suppress this effect, and to make the device faster, it is in principle essential to extremely reduce the junction depth at the source/drain extension regions of the device. For example, devices of the 0.1 μm design-rule generation require a junction depth of 50 nm. Moreover, the 0.05 μm design-rule generation requires the junction depth to be as little as 10 nm.

Therefore, it is necessary to develop a technique for introducing the semiconductor impurity layer into a very shallow junction depth of about 10 nm (which is called the ultra-shallow junction layer hereinafter) and activating the layer as a semiconductor. The decrease in the junction depth of the source/drain extension regions also causes an increase in the parasitic resistance, which makes it more difficult to increase the device speed. This means that it is necessary to create a junction that is ultra-shallow and yet has a very low resistance. This requirement is difficult to satisfy. Therefore, in addition to the technique for creating a heavily doped ultra-shallow junction layer, it is essential to establish a technique for electrically activating the layer to create an ultra-shallow junction layer having a low-resistance while suppressing the atomic diffusion. Whether or not these techniques can be established is one of process limits that will determine the future development of the MOS technology. Particularly, MOS transistors of the 0.1 μm generation or later require an ultra-shallow junction layer having a depth within the range from 10 to 30 nm and a sheet resistance of about 1 kΩ/sq. or lower.

Conventional techniques for activating a semiconductor impurity include rapid thermal annealing (RTA) and laser surface melting (by irradiation of nanoseconds pulse). In principle, both activation techniques are variations of thermal annealing.

These activation techniques, which are based on thermal principles, has a problem in that they also cause unnecessary diffusion of heat into deeper portions of the substrate, so that they cannot be easily applied to p-channel metal-oxide semiconductor (PMOS) transistors (i.e. transistors having a boron-doped layer), particularly. For example, if a boron-doped layer having a junction depth of 20 nm is activated by an RTA treatment under typical conditions (at 1000 degrees Celsius for 10 seconds), the boron atoms diffuse to a depth of about 40 nm.

In one of the conventionally known techniques for creating an ultra-shallow junction layer while suppressing the atomic diffusion, the semiconductor dopant layer is irradiated with an ultra-short pulsed laser light to be activated at a low temperature (see Patent Document 1). According to this technique, the ultra-short pulsed laser radiation causes a direct or selective phonon excitation to activate the dopant layer at a low temperature, whereby an ultra-shallow junction layer is formed. References relating to the phonon include Non-Patent Documents 1 to 3.

Regarding the creation of the ultra-shallow junction layer, another processing technique for creating both the ultra-shallow junction layer and the source/drain extension region, called the elevated source/drain technique, has been proposed (Patent Document 2) in parallel with the above-described technique for the low temperature activation of the dopant layer itself. The elevated source/drain technique is expected to be a mainstream technique in a generation that requires a depth of about 10 nm or smaller in the international roadmap (see Non-Patent Document 4).

The elevated source/drain technique includes the steps of performing reactive plasma etching to create a shallow recess in the vicinity of the gate electrode of the semiconductor substrate and then epitaxially growing a doped silicon layer within the recess to create an ultra-shallow extension region (i.e. the ultra-shallow junction layer) and source/drain regions.

As a mode of this manufacturing process, a processing technique has been proposed in which a shallow recess having a depth of about 10 mm is created by a process including the steps of implanting ions into a semiconductor substrate to amorphize the surface of the substrate by a depth of about 10 nm and then performing reactive plasma etching with a halogen gas in which the amorphous phase is more selectively etched than the crystalline phase (see Patent Document 3). After the ion-implanting process for amorphization and the etching process, a silicon layer (containing a semiconductor impurity) is epitaxially grown to fill the recess. This technique allows ultra-shallow junction layers to be created with high controllability.

[Patent Document 1] Unexamined Japanese Patent Publication No. 2001-338894, disclosed on Dec. 7, 2001

[Patent Document 2] Unexamined Japanese Patent Publication No. H08-153688, disclosed on Jun. 11, 1996

[Patent Document 3] Unexamined Japanese Patent Publication No. 2003-109969, disclosed on Apr. 11, 2003

[Non-Patent Document 1] F. Favot and A. D. Corso, Physical Review B vol. 60 (1999) p. 11427

[Non-Patent Document 2] Shinichi, NAKAJIMA, Muneaki HASE and Kohji MIZOKUCHI, BUTSURI, the Bulletin of the Physical Society of Japan, vol. 53, No. 8 (1999), pp. 607-611

[Non-Patent Document 3] Satoshi ADACHI, R. M. Koehl and K. A. Nelson, BUTSURI, the Bulletin of the Physical Society of Japan, vol. 54, No. 5 (1999), pp. 357-363

[Non-Patent Document 4] International technology Roadmap for Semiconductors, 2001 Edition, Front End Processes

### DISCLOSURE OF THE INVENTION

### Problem to be Solved by the Invention

The processing technique disclosed in Patent Document 1 has problems to be solved for its mass production. The most serious problem relates to the damaging of the semiconductor surface due to the irradiation of the ultra-short pulsed laser light and the poor reproducibility due to the damage. In mass production, it is necessary to perform the process free from damage over the entire chip with high reproducibility. The irradiation of the ultra-short pulsed laser light, however, uses a very strong electric field and easily causes an ablation of the semiconductor surface. The ablation hereby means a phenomenon in which the material is heated by the ultra-short pulsed laser to a temperature above its melting point and evaporates or sublimes until the heated portion is removed. As the junction becomes shallower, the damage of the semiconductor surface rejoin has more significant effects on the ultra-shallow dopant layer itself and its electrical characteristics (an increase in the sheet resistance). Thus, it is difficult to create a junction having a uniform depth with high reproducibility.

In the processing technique disclosed in Patent Document 3, it is necessary to obtain a clean surface of silicon in order to stabilize the epitaxial growth. However, as a result of the ion implantation for amorphization, some ions or atoms resulting from the ion implantation remain on the interface after the etching process. Even if the element used in the ion implantation is the same as that of the semiconductor substrate, an implantation defect inevitably remains on the interface because the depth-directional range of the ions during the ion-implanting process is distributed. Thus, the present technique cannot prevent foreign atoms (if the implantation uses foreign atoms) or lattice defects (if the implantation uses the same kind of atoms) from being present on the interface. The presence of the atoms or defects makes the interface unsuitable for the epitaxial growth because they cause a lattice mismatch during the epitaxial growth. Etching this amorphized region to create a recess and then filling the recess with a semiconductor layer provides a source/drain extension region that does not have a uniform depth. Thus, the semiconductor impurity layer resulting from the epitaxial growth does not have a high quality.

In view of the above problems, the present invention intends to provide: a surface modification method for a solid sample, capable of creating a uniform interface free from foreign atoms or lattice defects resulting from the ion implantation; an impurity activation method capable of lowering the sheet resistance; and a method for manufacturing a semiconductor device, capable of creating source/drain extension regions having a uniform depth with high reproducibility.

### Means for Solving the Problems

To solve the above problems, the surface modification method for a solid sample according to the present invention includes a step of irradiating the solid sample with a pulsed laser light having a pulse width within the range from 10 to 1000 femtoseconds so as to modify only the surface layer of the solid sample from a crystalline phase to an amorphous phase or from an amorphous phase to a crystalline phase.

Any solid sample has an interatomic force working among the internal atoms. The interatomic force works as a restoring force (spring force) that follows Hooke's law with respect to small displacements. Therefore, if an atom vibrates due to its thermal motion or an external force, the vibration is transmitted to neighboring atoms, thus causing a coupled vibration. This is called lattice vibration. If it occurs within a solid sample, the vibration is quantized and hence called phonon. Each kind of material has inherent values of the atomic mass, the interatomic distance and the interatomic force, which corresponds to the spring constant of the restoring force. Therefore, the frequency and the wave number of the phonon are interdependent. This relation is called dispersion relation.

When a solid sample is irradiated with light, an elastic deformation coupled with the light occurs due to a local rise in the temperature (thermal coupling) or a local disturbance of the dielectric polarization (optical elastic coupling). With this elastic deformation as an external force, if the solid sample is irradiated with light (electromagnetic waves) within the range of the phonon frequency, coherent phonons can be excited due to the induced Raman scattering. For example, Non-Patent Document 1 discloses the dispersion relation of the phonons in the single crystal silicon, which shows that the frequencies of the phonons are within the range from 10 GHz to 10 THz. To generate coherent electromagnetic waves within this frequency band, a millimeter-wave oscillating tube, such as a gyrotron, can be used for a frequency band from 10 GHz to 100 GHz (millimeter-wave range). In contrast, the frequency range from 100 GHz to 10 THz is an unexplored electromagnetic wave region, called the “terahertz radiation,” which has not been covered by any single oscillator.

Accordingly, within the frequency range from 10 GHz to 100 GHz, it is possible to excite a phonon by generating coherent electromagnetic waves within the millimeter band with a gyrotron or other oscillators and then irradiating the solid sample with the electromagnetic waves so as to coherently vibrate the dielectric polarization on the surface of the solid sample by the alternating electric field of the coherent electromagnetic waves.

Within the electromagnetic wave region from 100 GHz to 10 THz, i.e. the terahertz radiation, when two coherent electromagnetic waves having frequencies ω1 and ω2 (ω1<ω2), whose wavelengths are slightly different, are cast onto the crystal, the electromagnetic waves cause a simulated scattering and it develops into a coherent phonon, if the difference between the two frequencies, ω1−ω2, satisfies the following equation:
ω1−2=ω0 (1)
where ω0 is the vibration frequency of the phonon. Therefore, if a coherent electromagnetic wave generator having a spectrum width (frequency band) broader than ω0 is used, the spectrum contains different frequency components that behave as ω1 and ω2. Thus, the above condition can be satisfied with a single coherent electromagnetic wave generator. The results of research on the coherent phonon excitation based on the above-described principle are also utilized in the imaging of the excited phonon or other technical fields in the physical properties research (see Non-Patent Documents 2 and 3).

The pulse width (Δt) and the frequency bandwidth (Δω) of the coherent electromagnetic wave beam satisfy the following equation:
Δt−Δω<2 ln 2/π (2).
Therefore, a coherent electromagnetic wave having a pulse width within the range from 10 to 1000 femtoseconds, which can be generated with a titanium-sapphire laser or other devices, will have a frequency bandwidth within the range from 1 to 100 THz. Equation (1) can be satisfied by using a difference frequency within the frequency region.

Accordingly, in the present invention, a pulsed laser light having a pulse width within the range from 10 to 1000 femtoseconds is cast onto the solid sample to rearrange the atoms within only the surface layer of the sample so that they are modified from a crystalline phase to an amorphous phase or from an amorphous phase to a crystalline phase, as explained earlier. This process modifies the surface of the solid sample without implanting ions. Therefore, the modified layer thereby obtained has a uniform interface free from residual foreign ions.

In addition to the construction described earlier, the surface modification method for a solid sample according to the present invention is further characterized in that:

in the relationship between the ablation rate of the solid sample due to the irradiation of the pulsed laser light and the laser fluence of the pulsed laser light, the laser fluence value that gives the maximum value of the gradient of the ablation rate with respect to the laser fluence is identified as the threshold laser fluence; and

the solid sample is irradiated with the pulsed laser light with a laser fluence equal to or lower than the threshold laser fluence.

According to the above construction, the laser fluence value that gives the maximum value of the gradient of the ablation rate with respect to the laser fluence is identified as the threshold laser fluence, and the solid sample is irradiated with the pulsed laser light with a laser fluence equal to or lower than the threshold laser fluence. The gradient of the ablation rate with respect to the laser fluence rapidly and clearly changes at a specific threshold laser fluence and has the maximum value. Therefore, it is possible to lower the ablation rate by irradiating the solid sample with a pulsed laser light with a laser fluence equal to or lower than the threshold laser fluence. As a result, the damage of the modified layer is further reduced.

In addition to the construction described earlier, the surface modification method for a solid sample according to the present invention is further characterized in that the solid sample is made of a semiconductor material, and the semiconductor material is irradiated with an electromagnetic wave to excite the valence electrons to the conduction band before the irradiation of the pulsed laser light.

According to the above construction, the solid sample is made of a semiconductor material, and the valence electrons within the semiconductor material are excited to the conduction band before the irradiation of the pulsed laser light. Therefore, the semiconductor material is in an excited state when it is irradiated with the pulsed laser light. As the excitation level of the semiconductor material at the moment of irradiation of the pulsed laser light becomes higher, the pulsed laser light has a higher level of exciting effect, causing a non-linear increase of the pulse excitation process. Thus, without increasing the laser fluence (and causing more ablation), the surface can be excited by the pulsed laser light and the surface of the semiconductor material can be modified from a crystalline phase to an amorphous phase or from an amorphous phase to a crystalline phase.

In addition to the construction described earlier, the surface modification method for a solid sample according to the present invention is further characterized in that the aforementioned electromagnetic wave has a wavelength corresponding to an energy level higher than the band gap within the semiconductor material.

According to the above construction, the semiconductor material absorbs the electromagnetic wave to be easily excited. As a result, the exciting effect of the pulsed laser light is further improved.

In addition to the construction described earlier, the surface modification method for a solid sample according to the present invention is further characterized in that the pulsed laser light is a circularly polarized light.

If the laser fluence is the same, the electric field strength of a circularly polarized light equals that of a linearly polarized light divided by the square root of two. Therefore, using a circularly polarized light as the pulsed laser light as in the above construction further impedes the ablation.

To solve the problems described earlier, the impurity activation method according to the present invention is characterized in that:

an impurity layer whose impurity concentration is higher than that of a semiconductor substrate is formed on the semiconductor substrate; and

the impurity layer is irradiated with a pulsed laser light having a pulse width within the range from 10 to 1000 femtoseconds in order to activate the impurity layer, where the sheet resistance of the impurity layer after the irradiation of the pulsed laser light is controlled by changing irradiation conditions including the pulse width, the laser fluence and the number of pulse shots of the pulsed laser light.

According to the above construction, the sheet resistance of the impurity layer after the irradiation of the pulsed laser light is controlled by changing irradiation conditions including the pulse width, the laser fluence and the number of pulse shots of the pulsed laser light. The sheet resistance of the impurity layer after the irradiation of the pulsed laser light significantly depends on irradiation conditions including the pulse width, the laser fluence and the number of pulse shots of the pulsed laser light. Therefore, the sheet resistance of the impurity layer after the irradiation of the pulsed laser light can be controlled by changing the irradiation conditions. Thus, the sheet resistance can be easily controlled so that it takes a desired, smaller value.

In addition to the construction described earlier, the impurity activation method according to the present invention is further characterized in that:

in the relationship between the pulse width of the pulsed laser light and the sheet resistance of the impurity layer after the irradiation of the pulsed laser light, the gradient of the sheet resistance with respect to the pulse width changes at a specific threshold pulse width;

the gradient within the range below the threshold pulse width is larger than that within the range above the threshold pulse width; and

the impurity layer is irradiated with the pulsed laser light with a pulse width equal to or smaller than the threshold pulse width.

According to the above construction, the impurity layer is irradiated with a pulse laser light having a pulse width equal to or smaller than the threshold pulse width. As a result, the sheet resistance of the impurity layer after the irradiation of the pulsed laser light is further lowered.

In addition to the construction described earlier, the impurity activation method according to the present invention is further characterized in that:

in the relationship between the pulse width of the pulsed laser light and the sheet resistance of the impurity layer after the irradiation of the pulsed laser light, the sheet resistance takes a minimum value at a specific laser fluence; and

the impurity layer is irradiated with the pulsed laser light at a laser fluence that gives a substantially minimal value of the sheet resistance.

According to the above construction, the impurity layer is irradiated with the pulsed laser light at a laser fluence that gives a substantially minimal value of the sheet resistance. As a result, the sheet resistance of the impurity layer after the irradiation of the pulsed laser light is further lowered.

In addition to the construction described earlier, the impurity activation method according to the present invention is further characterized in that:

in the relationship between the number of pulse shots of the pulsed laser light and the sheet resistance of the impurity layer after the irradiation of the pulsed laser light, the sheet resistance takes a minimum value at a specific number of pulse shots; and

the impurity layer is irradiated with a pulsed laser light at a number of pulse shots that gives a substantially minimal value of the sheet resistance.

According to the above construction, the impurity layer is irradiated with a pulsed laser light at a number of pulse shots that gives a substantially minimal value of the sheet resistance. As a result, the sheet resistance of the impurity layer after the irradiation of the pulsed laser light is further lowered.

In addition to the construction described earlier, the impurity activation method according to the present invention is further characterized in that the impurity layer is irradiated with an electromagnetic wave to excite the valence electrons to the conduction band before the irradiation of the pulsed laser light.

According to the above construction, the impurity layer is in an excited state when it is irradiated with the pulsed laser light. As the excitation level of the impurity layer at the moment of irradiation of the pulsed laser light becomes higher, the pulsed laser light has a higher level of exciting effect, causing a non-linear increase of the pulse excitation process. Thus, without increasing the laser fluence (and causing more ablation), the surface can be excited by the pulsed laser light and the impurity layer can be activated.

In addition to the construction described earlier, the impurity activation method according to the present invention is further characterized in that the aforementioned electromagnetic wave has a wavelength corresponding to an energy level higher than the band gap within the semiconductor material.

According to the above construction, the semiconductor material easily absorbs the electromagnetic wave, so that the impurity layer can be easily excited. As a result, the exciting effect of the pulsed laser light is further improved.

In addition to the construction described earlier, the impurity activation method according to the present invention is further characterized in that the pulsed laser light is a circularly polarized light.

If the laser fluence is the same, the electric field strength of a circularly polarized light equals that of a linearly polarized light divided by the square root of two. Therefore, using a circularly polarized light as the pulsed laser light as in the above construction further impedes the ablation and reduce the damage of the surface of the impurity layer.

In addition to the construction described earlier, the impurity activation method according to the present invention is further characterized in that, when or before the impurity layer is formed, a semiconductor atom is added to or introduced into the region where the impurity layer is to be formed and the region is amorphized.

In addition to the construction described earlier, the impurity activation method according to the present invention is further characterized in that the semiconductor substrate is made of silicon and the semiconductor atom is either silicon or germanium.

According to the above construction, the region where the impurity layer is to be formed is subjected to a pre-amorphization treatment. This treatment suppresses the enhanced diffusion of the impurity ion during the activation by the irradiation of the pulsed laser light, so that the distribution of the impurity can be controlled with high accuracy.

To solve the problems described earlier, the method for manufacturing the semiconductor device according to the present invention is characterized in that the device includes:

a gate electrode formed on a semiconductor substrate via a gate insulating film; and

an impurity-enriched source-side region and an impurity-enriched drain-side region, both formed on the semiconductor substrate so that the two regions face each other across a channel region at which the gate electrode is formed, and the method includes:

an amorphous layer formation process in which an amorphous layer is created between the channel region and the impurity-enriched source-side region as well as between the channel region and the impurity-enriched drain-side region by casting a pulsed laser light having a pulse width within a range from 10 to 1000 femtoseconds;

a recess formation process for creating recesses in the semiconductor substrate by selectively etching the amorphous layer; and

a source/drain extension region formation process for creating source/drain extension regions by filling the recesses with semiconductor layers whose impurity concentration is higher than that of the semiconductor substrate.

According to the above construction, an amorphous layer is created between the channel region and the impurity-enriched source-side region as well as between the channel region and the impurity-enriched drain-side region by casting a pulsed laser light having a pulse width within the range from 10 to 1000 femtoseconds in the amorphous layer formation process. This process can create amorphous layers on the semiconductor substrate without implanting ions, so that no ions remain in the recesses formed by the recess formation process. Furthermore, casting a uniformly distributed laser light creates a uniform interface free from implantation defects, which would remain if the ion implantation were performed. Thus, the source/drain extension regions created by the source/drain formation process have no foreign atoms or lattice defects remaining on their interface; if such atoms or defects were present, they would cause a lattice mismatch during the epitaxial growth. Thus, an interface suitable for forming a high-quality semiconductor impurity layer by epitaxial growth is obtained. As a result, the performance of the semiconductor device is further improved.

To solve the problems described earlier, the method for manufacturing the semiconductor device according to the present invention is characterized in that the device includes:

a gate electrode formed on a semiconductor substrate via a gate insulating film; and

an impurity-enriched source-side region and an impurity-enriched drain-side region, both formed on the semiconductor substrate so that the two regions face each other across a channel region at which the gate electrode is formed, and the method includes:

an impurity layer formation process in which impurity layers are formed by implanting an impurity element into a predetermined depth between the channel region and the impurity-enriched source-side region as well as between the channel region and the impurity-enriched drain-side region; and

an impurity layer activation process for activating the impurity layers by the impurity activation methods described earlier.

According to the above construction, the impurity layer is activated by the impurity activation methods described earlier during the impurity layer activation process. This process activates the impurity layer at the surface of the substrate while suppressing the diffusion of the impurity atoms into deeper portions, thus forming an ultra-shallow semiconductor junction layer. As a result, the performance of the semiconductor device is further improved.

### EFFECTS OF THE INVENTION

To solve the above problems, the surface modification method for a solid sample according to the present invention includes a step of irradiating the solid sample with a pulsed laser light having a pulse width within the range from 10 to 1000 femtoseconds so as to modify only the surface layer of the solid sample from a crystalline phase to an amorphous phase or from an amorphous phase to a crystalline phase. Since the ion implantation process is not performed, the modified layer formed on the solid sample can have a uniform interface free from foreign atoms or lattice defects.

In the impurity activation method according to the present invention, the sheet resistance of the impurity layer after the irradiation of the pulsed laser light is controlled by changing irradiation conditions including the pulse width, the laser fluence and the number of pulse shots of the pulsed laser light. Thus, the sheet resistance of the impurity layer after the irradiation of the pulsed laser light can be easily controlled so that it takes a desired, smaller value.

### BRIEF DESCRIPTION OF THE DRAWINGS

FIG. 1 is a set of sectional views showing the manufacturing process of a semiconductor device as an embodiment of the present invention.

FIG. 2 is a schematic diagram showing an irradiation system for irradiating a solid sample with an ultra-short pulsed laser light.

FIG. 3 is a photograph taken with a transmission electron microscope (TEM), showing a section of a single-crystal silicon substrate irradiated with an ultra-short pulsed laser light.

FIG. 4 is a photograph taken with a TEM, showing a section of a single-crystal silicon substrate irradiated with an ultra-short pulsed laser light.

FIG. 5 is a graph showing the relationship between the ablation rate and the laser fluence of the ultra-short pulsed laser light.

FIG. 6 is a set of photographs showing a section of a single-crystal silicon substrate containing germanium implanted in the surface, which were taken with a TEM before and after an irradiation of the ultra-short pulsed laser light.

FIG. 7 is a sectional view showing the structure of a test element group (TEG) for measuring the sheet resistance of an impurity layer.

FIG. 8 is a graph showing the relationship between the sheet resistance of the TEG and the pulse width of the ultra-short pulsed laser light.

FIG. 9 is a graph showing the relationship between the sheet resistance of the TEG and the normalized laser fluence of the ultra-short pulsed laser light.

FIG. 10 is a graph showing the relationship between the sheet resistance of the TEG and the number of pulse shots of the ultra-short pulsed laser light.

FIG. 11 is a schematic diagram showing the construction of a measurement system for the time-resolved measurement of the dielectric constant in the vicinity of the surface of a solid sample by a reflection pump-probe method.

FIG. 12 is a graph showing the result of a time-resolved measurement of a reflectance by a reflection pump-probe method.

FIG. 13 is a series of graphs showing the results of time-resolved measurements of a reflectance using two pump beams, where (a) shows the result of a measurement in which the two pump beams were separately used, and (b), (c) and (d) show the results of measurements in which the time difference between the two pump beams was set at 0, 100 and 170 femtoseconds, respectively.

FIG. 14 is a sectional view showing the manufacturing process of a semiconductor device as another embodiment of the present invention.

### EXPLANATION OF NUMERALS

1 . . . Irradiation System
2 . . . Laser Light Source
3 . . . Polariscope
4 . . . Irradiation Optics Unit
5 . . . Chamber
6 . . . Sample Stage
7 . . . Solid Sample
11 . . . Single-Crystal Silicon Substrate
13 . . . P⁺Region
14 . . . Cobalt Silicide Layer
16 . . . Impurity Layer
21 . . . Semiconductor Substrate
22 . . . Device-separating Insulation Film
23 . . . Gate Insulation Film
24 . . . Gate Electrode
25 . . . Electrode Protection Film
26a, 26b . . . Amorphous Layer
27 . . . Recess
28 . . . Semiconductor-Embedded Layer
29 . . . Sidewall
30, 42 . . . Deep Diffusion Layer (Diffusion Layer)
31 . . . Source/Drain (S/D) Extension Region
32 . . . Silicide Layer (Electrode Region)
43 . . . Boron Ion-Implanted Layer (Impurity Layer)
51 . . . Charge Coupled Device (CCD) Camera
52 . . . Ultra-Short Pulsed Laser
53 . . . Ne-Laser
54 . . . Lens
55a, 55b, 55c . . . Corner Cube
56a, 56b, 56c . . . Half Mirror
71 . . . Test Element Group (TEG)

### BEST MODES FOR CARRYING OUT THE INVENTION

### Embodiment 1

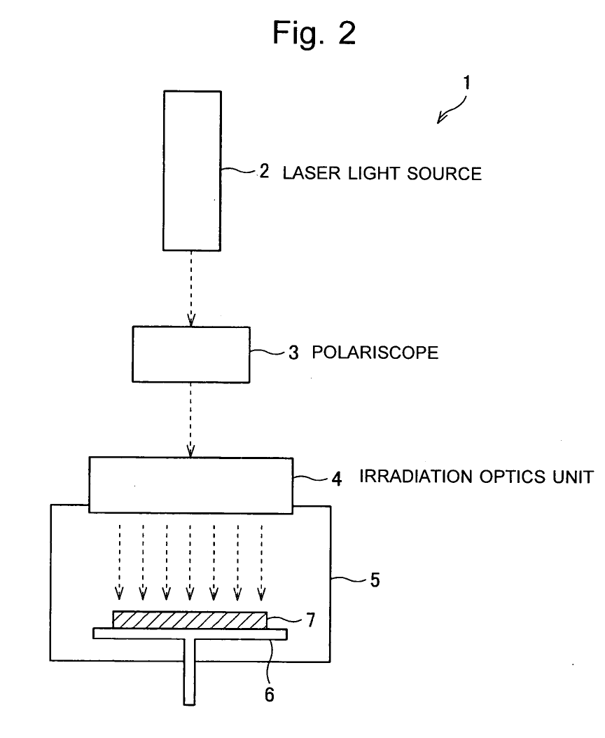

This section describes an embodiment of the present invention on the basis of FIGS. 2 to 6.

FIG. 2 is a schematic diagram showing an ultra-short pulsed laser irradiation system 1 of the present embodiment. As shown in FIG. 2, the irradiation system 1 includes a laser light source 2, a polariscope 3, an irradiation optics unit 4 and a chamber 5.

The laser light source 2 generates an ultra-short pulsed laser light having a pulse width within a range from 10 to 1000 femtoseconds, which corresponds to a frequency band from 1 to 100 THz. An example is a titanium-sapphire laser. The laser light source 2 can control the pulse width, the laser fluence, the number of pulse shots and the wavelength of the laser light to be produced. The laser fluence hereby means the density of radiation energy. The laser fluence is controlled through the output energy and the spot diameter of the laser light generated by the laser light source 2.

The polariscope 3, which consists of a polarizer and other components, is used to polarize the laser light produced by the laser light source 2. The polariscope 3 produces a linearly, circularly or elliptically polarized laser light.

The irradiation optics unit 4 includes optical components necessary for uniformly irradiating the solid sample 7 in the chamber 5 with the laser light received from the polariscope 3. The unit 4 converts the laser light that has passed through the polariscope 3 into a coherent electromagnetic wave suitable for irradiation and casts the wave onto the solid sample 7.

The chamber 5 forms a space for maintaining an inert atmosphere (e.g. nitrogen, helium or argon), a reducing atmosphere (e.g. hydrogen) or a degree of vacuum of 1×10⁻⁶ Torr (1 Torr=133.322 Pa) or lower. The chamber 5 contains a sample stage 6 inside, on which the solid sample 7 is set. The solid sample 7 is to be irradiated with a laser light that has been uniformly distributed by the irradiation optics unit 4.

### Example 1-1

In this example, the surface of a solid sample was modified using the above-described ultra-short pulsed laser irradiation system 1. In Example 1, a titanium-sapphire laser was used as the laser light source 2. The laser light was 800 nm in wavelength, 100 femtoseconds in pulse width and 250 mJ/cm² in laser fluence, and ten shots of the laser pulses were generated at a pulse repetition frequency of 1 kHz. A single-crystal silicon substrate was used as the solid sample 7.

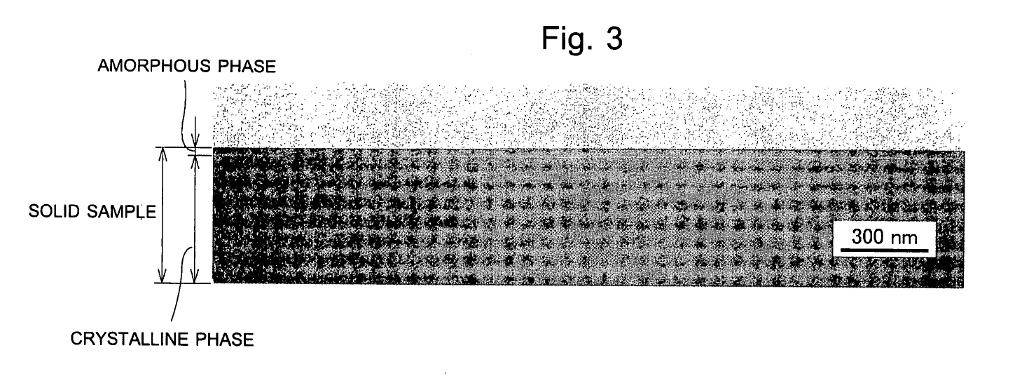

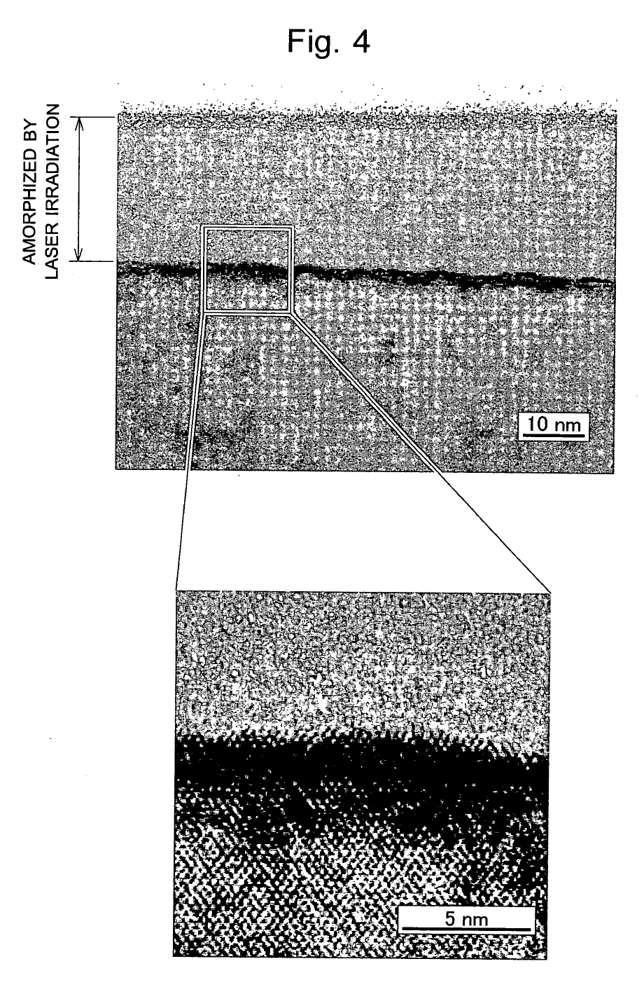

FIGS. 3 and 4 are lattice images of the surface portion of a single-crystal silicon substrate irradiated with an ultra-short pulsed laser light under the above conditions; the images were taken with a high-resolution transmission electron microscope (TEM) FIG. 4 is an enlarged image of FIG. 3.

FIGS. 3 and 4 show that the lattice is disordered in the superficial nanometer-region (whose thickness is about 24 nm in the present embodiment) of the single-crystal silicon substrate. This means that the region has changed from the crystalline phase to the amorphous phase. It is also clear that the interface between the crystalline phase and the amorphous phase is approximately flat and uniform.

Thus, it has been confirmed that the superficial nanometer-region of a single-crystal silicon substrate can be modified from a crystalline phase to an amorphous phase by irradiating the substrate with an ultra-short pulsed laser light. As opposed to conventional amorphization processes using the ion implantation technique, the present method allows no other elements to remain. The interface thereby created is free from foreign atoms or implantation defects and more uniform than that obtained by the ion implantation. As a result, it is possible to create an ultra-shallow junction layer with high controllability by etching the amorphized region by a reactive plasma etching process and then filling the resulting recess with a silicon layer (containing a semiconductor impurity) by epitaxial growth.

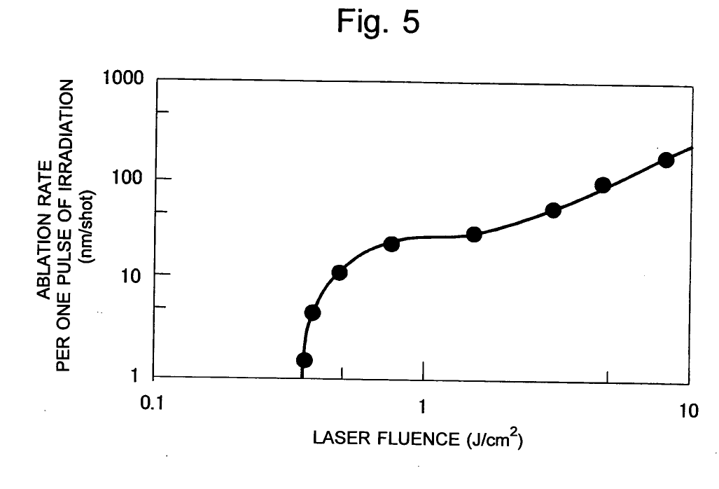

Subsequently, the ablation rate per one pulse shot was measured for various values of laser fluence. The ablation rate per one pulse shot hereby means the thickness by which the solid sample 7 is removed by one pulse shot due to ablation. FIG. 5 is a graph showing the result of a measurement using a laser light of 800 nm in wavelength and 100 femtoseconds in pulse width. As shown in FIG. 5, the gradient of the ablation rate with respect to the laser fluence is maximized at a laser fluence of about 0.4 J/cm². With this value as the threshold laser fluence, the ablation rate makes a remarkable (rapid and clear) change. If the laser fluence is equal to or smaller than the threshold (i.e. 0.4 J/cm² in the present case), the ablation rate is close to zero, and the surface of the single-crystal silicon substrate can be modified from the crystalline phase to the amorphous phase at a low ablation rate. As a result, the thickness of the amorphous phase becomes further uniform. In the amorphization process shown in FIGS. 3 and 4, the laser irradiation was performed at a laser fluence of 0.25 J/cm², which is lower than the threshold at which the gradient of the ablation rate with respect to the laser fluence is maximized.

### Example 1-2

As opposed to Example 1-1, the present example is an example in which an amorphous phase was modified to a crystalline phase. As in the previous example, a titanium-sapphire laser was used as the laser light source 2. A single-crystal silicon substrate, on which an amorphous layer of about 10 nm in thickness was formed by implanting germanium ions by 5 keV, was used as the solid sample 7.

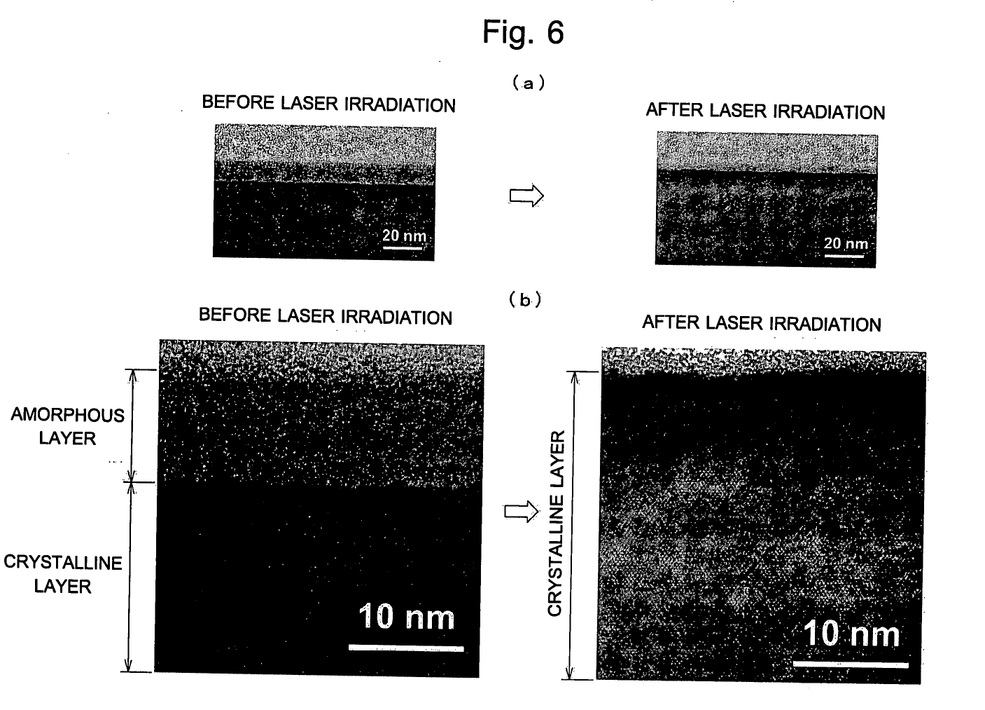

FIG. 6 shows the lattice images of the surface region of the single-crystal silicon substrate with the amorphous layer formed on it. The images were taken with a TEM before and after the irradiation of the ultra-short pulse laser light, respectively. FIG. 6(b) is an enlarged image of FIG. (a).

As shown in FIG. 6, it was confirmed that the amorphous layer formed from the surface to a depth of 10 nm was changed to a crystalline phase by an irradiation of an ultra-short pulsed laser light. This proves that an amorphous phase can be changed to a crystalline phase by an irradiation of an ultra-short pulsed laser light.

### Example 1-3

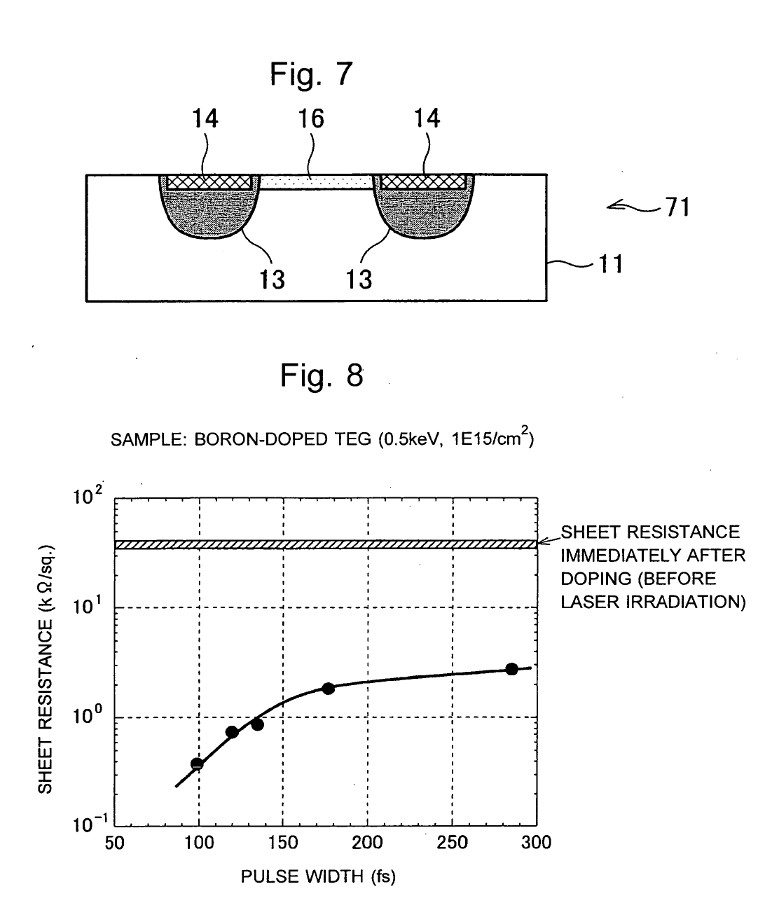

This example relates to the method for activating an impurity layer on a silicon substrate by an irradiation of an ultra-short pulsed laser light. As explained earlier, what needs to be hereby achieved is to lower the sheet resistance of the impurity layer after the activation. To measure the sheet resistance of the impurity layer activated by an irradiation of an ultra-short pulsed laser light, the present example used a test element group (TEG) 71 constructed as shown in FIG. 7.

A method of creating the TEG is hereby explained.

On the surface of an n-type single-crystal silicon substrate 11, a resist is formed except for two strips of electrode regions, each having a width of 164 μm and separated from each other by a distance of 200 μm. With the resist as a mask, an ion implantation process is performed to implant a boron impurity of 3×10¹⁵ to 4×10¹⁵ ions/cm² by an implantation energy of 15 to 100 keV. Subsequently, an annealing thermal treatment is performed to create a P⁺ region 13 within the electrode region.

Next, a thin film of cobalt (Co) is put onto the surface of the single-crystal silicon substrate masked with the resist, and the substrate is heated. This treatment makes the cobalt react with the silicon to form a cobalt silicide (CoSi₂) layer 14.

Then, the resist is removed and another resist is put on the surface except for the two electrode regions on which the cobalt silicide layer 14 is formed. Subsequently, with the resist as a mask, a boron impurity of 1×10¹⁵ ions/cm² is implanted into the inter-electrode region (i.e. the region between the two electrode regions) by an implantation energy of 0.5 keV, thus creating an impurity layer 16.

Then, the resist is removed to obtain a TEG 71 having two strips of electrode regions each consisting of the P⁺ region 13 covered with the cobalt silicide layer 14, and the impurity layer 16 between the two electrode regions. The sheet resistance of the region between the two electrode regions recorded a high value of 40 kΩ/sq. This is partly because the impurity layer 16 between the two electrode regions is not activated, and partly because the two electrode regions and the single-crystal silicon substrate 11 are in the form of a PNP reverse bias structure.

Next, an ultra-short pulsed laser light generated by the irradiation system 1 was cast onto the TEG 71 as the solid sample 7 to activate the impurity layer 16. Subsequently, the sheet resistance of the inter-electrode region was measured. When activated, the impurity layer 16 comes in ohmic contact with the P⁺ region 13, which lowers the sheet resistance. Therefore, the effect of electrical activation by the laser irradiation can be evaluated by measuring the sheet resistance of the inter-electrode region.

FIG. 8 shows the measurement result indicating the relationship between the pulse width and the sheet resistance of the inter-electrode region irradiated with a laser light having a wavelength of 800 nm generated at a pulse repetition frequency of 1 kHz, in which a titanium-sapphire laser was used as the laser light source 2.

As shown in FIG. 8, the sheet resistance decreases as the pulse width of the irradiated laser light is decreased. When the pulse width is equal to or smaller than 300 femtoseconds, the sheet resistance is equal to or lower than 2 kΩ/sq. The gradient of the sheet resistance with respect to the pulse width changes at a specific threshold, which is about 150 femtoseconds in FIG. 8. The gradients of the sheet resistance with respect to the pulse width within the range where the pulse width is below the threshold are larger than those within the range where the pulse width is above the threshold. Setting the pulse width within the range at or below the threshold results in a lower sheet resistance. There is a problem that setting the pulse width smaller than 50 femtoseconds would increase the cost for generating the laser light.

The above result suggests that the pulse width should be preferably within a range from 50 to 300 femtoseconds if the sheet resistance should be lowered from the initial value of 40 kΩ/sq. by one or more digits. It is also preferable to set the pulse width equal to or smaller than a value corresponding to the point where the gradient of the sheet resistance with respect to the pulse width starts decreasing against an increase of the pulse width. These settings further lower the sheet resistance.

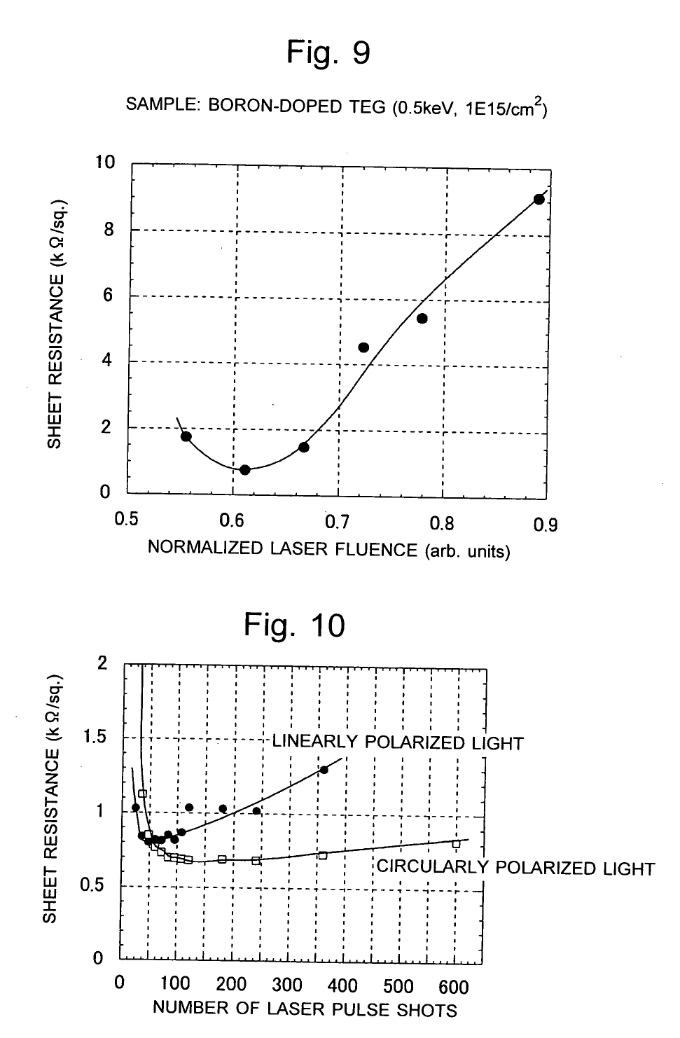

FIG. 9 shows the measurement result indicating the relationship between the laser fluence and the resistance of the impurity layer irradiated with a laser light having a wavelength of 800 nm generated at a pulse repetition frequency of 1 kHz, in which a titanium-sapphire laser was used as the laser light source. The abscissa indicates the normalized laser fluence, which takes a value of 1 when the output energy of the titanium-sapphire laser is maximized.

As shown in FIG. 9, it was confirmed that the sheet resistance takes a minimum value when the normalized laser fluence is a specific value, which is about 0.61 in FIG. 9. The reason for this phenomenon is as follows: When the laser fluence is very low, the laser light is too weak to activate the impurity layer 16. Therefore, the sheet resistance is as low as the value achieved by ion implantation. When the laser fluence becomes higher, an activation of the impurity layer 16 takes place, so that the sheet resistance rapidly falls. When the laser fluence is further raised, the device becomes damaged (due to amorphization or ablation), so that the sheet resistance increases.

Thus, the sheet resistance is minimized at a certain value of laser fluence, and it is preferable to cast the laser light at the aforementioned laser fluence in order to lower the resistance the impurity layer 16.

FIG. 10 shows the measurement result indicating the relationship between the number of pulse shots and the sheet resistance irradiated with a laser light having a wavelength of 800 nm generated at a pulse repetition frequency of 1 kHz, in which a titanium-sapphire laser was used as the laser light source. The measurement was performed using two kinds of polarized light generated with the polariscope 3: linearly polarized light and circularly polarized light.

As shown in FIG. 10, it was confirmed that the sheet resistance has a minimum value at a certain number of pulse shots for each kind of polarization. Within the range at or below the number of pulse shots that gives the minimum value, the sheet resistance becomes lower as the number of pulse shots increases. This is due to the activation of the boron ion impurity. In contrast, within the range above the number of pulse shots that gives the minimum value, the sheet resistance becomes higher as the number of pulse shots increases. This is because the impurity is removed from the surface due to the ablation.

Thus, the sheet resistance is minimized at a certain value of the number of pulse shots, and it is preferable to cast the ultra-short pulsed laser light by the aforementioned number of pulse shots in order to lower the sheet resistance.

The comparison of the linearly polarized light and the circularly polarized light in FIG. 10 shows that the circularly polarized light produces lower sheet resistances. The reason is as follows: If the laser fluence is the same, the electric field strength of the circularly polarized light equals that of the linearly polarized light divided by the square root of two, and the weaker electric field causes less ablation. Accordingly, it is preferable to circularly polarize the ultra-short pulsed laser light.

### Embodiment 2

In the previous embodiment, the solid sample 7 was irradiated with an ultra-short pulsed laser light to excite the surface of the solid sample 7 before the modification of the surface (e.g. modification from a crystalline phase to an amorphous phase) or activation of the impurity layer 16. In general, excitation of a surface can be done by increasing the laser fluence. However, as described previously, this operation is undesirable because it causes ablation. The present embodiment provides a method for further helping the surface excitation of the solid sample 7 while suppressing the ablation.

In the present embodiment, the solid sample 7 made of a semiconductor material is irradiated with an electromagnetic wave to excite the valence electrons to the conduction band before the irradiation of the ultra-short pulsed laser light. Examples of the excitation methods include a multi-photon process; in a preferable method, the solid sample 7 is irradiated with a light having a wavelength that can be easily absorbed by the sample (i.e. a wavelength corresponding to a photon energy level higher than the band gap of the solid sample 7). The pre-excitation of the valence electrons to the conduction band brings the surface into a highly excited state at the moment of the irradiation of the ultra-short pulsed laser. As a result, the ultra-short pulsed laser has a more remarkable exciting effect.

The following example provides a basis for claiming the effectiveness of the pre-excitation process in which the solid sample 7 is irradiated with a light having a wavelength corresponding to a photon energy level higher than the band gap of the sample before the irradiation of the ultra-short pulsed light.

### Example 2-1

A time-resolved measurement of the dielectric constant in the vicinity of the surface of a solid sample by a reflection pump-probe method was performed to investigate the relaxation process of the electronic state or the vibration-excited state of the phonon in the surface excited by the ultra-short pulsed laser. In this type of time-resolved measurement, information about a change of the dielectric constant is detected as a change of the reflectance; the solid sample is disturbed with a pump beam and the change in the reflectance of a probe light having a time difference from the pump beam is measured. The probe light is much weaker than the pump beam.

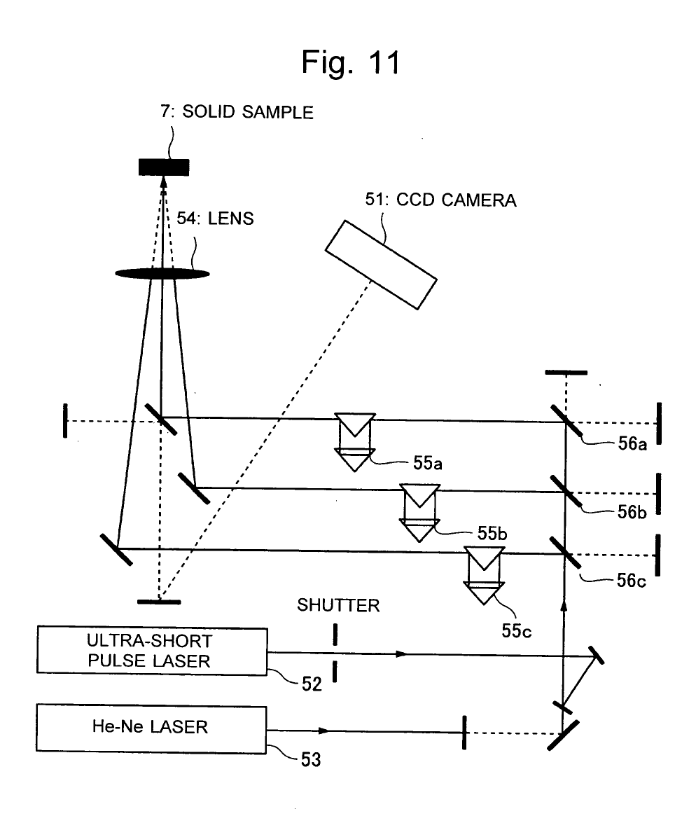

FIG. 11 is a schematic diagram showing the construction of a measurement system for the time-resolved measurement of the dielectric constant in the vicinity of the surface of a solid sample by a reflection pump-probe method. As shown in FIG. 11, an ultra-short pulsed laser light generated by the ultra-short pulse laser 52 using a titanium-sapphire laser is separated by the half mirrors 56a, 56b and 56c into two pump beams and one probe beam. The corner cubes 55a, 55b and 55c, each mounted on a stage, are actuated with stepper motors (not shown) to adjust the optical path difference. The pump beams and the probe beam are converged by the lens 54 onto the solid sample 7. Using this system, the time difference between the pump beams and the probe beam was scanned and the temporal change of the differential reflectance of the probe light was measured. In addition, the surface of the sample was observed before and after the irradiation of the ultra-short pulsed laser light with a magnifying optics system (not shown) and the charge coupled device (CCD) camera 51 in order to check that the irradiation had not caused ablation or similar change on the surface. The He—Ne laser 53 was used to illuminate the sample surface during the observation and to align the optics system.

The solid sample 7 hereby used was an n-type single-crystal silicon (100) substrate. The ultra-short pulse laser 52 was controlled to generate a laser light having a wavelength of 800 nm and a pulse width of 100 femtoseconds at a pulse repetition frequency of 1 kHz.

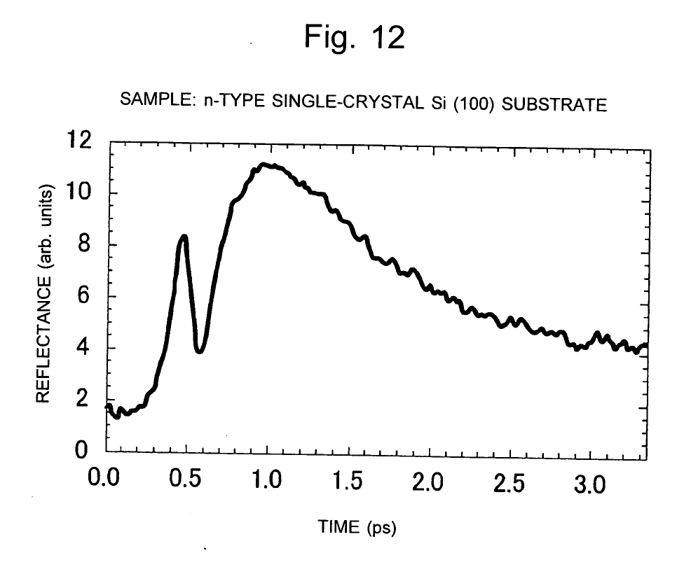

FIG. 12 is a graph showing the result of the time-resolved measurement of the reflectance by the reflection pump-probe method. It should be noted that the graph in FIG. 12 was obtained using only one pulse of laser as the pump beam for excitation. The signal that is first detected from the start of the irradiation of the pump beam, which corresponds to the peak at 0.5 picoseconds in FIG. 12, has approximately the same pulse width as that of the irradiated pulse. The next component, whose peak is delayed by 0.5 picoseconds and appears at about 1.0 picosecond in FIG. 12, is damped with a time constant (1/e, where e is the base of the natural logarithm) of equal to or longer than 2 picoseconds. This component, damped with a long time constant that exceeds 2 picoseconds, indicates the temporal change of the electrical sensitivity or dielectric constant that results from the creation of electron-hole plasma by carriers optically excited to the conduction band and its relaxation to the band edges or other regions.

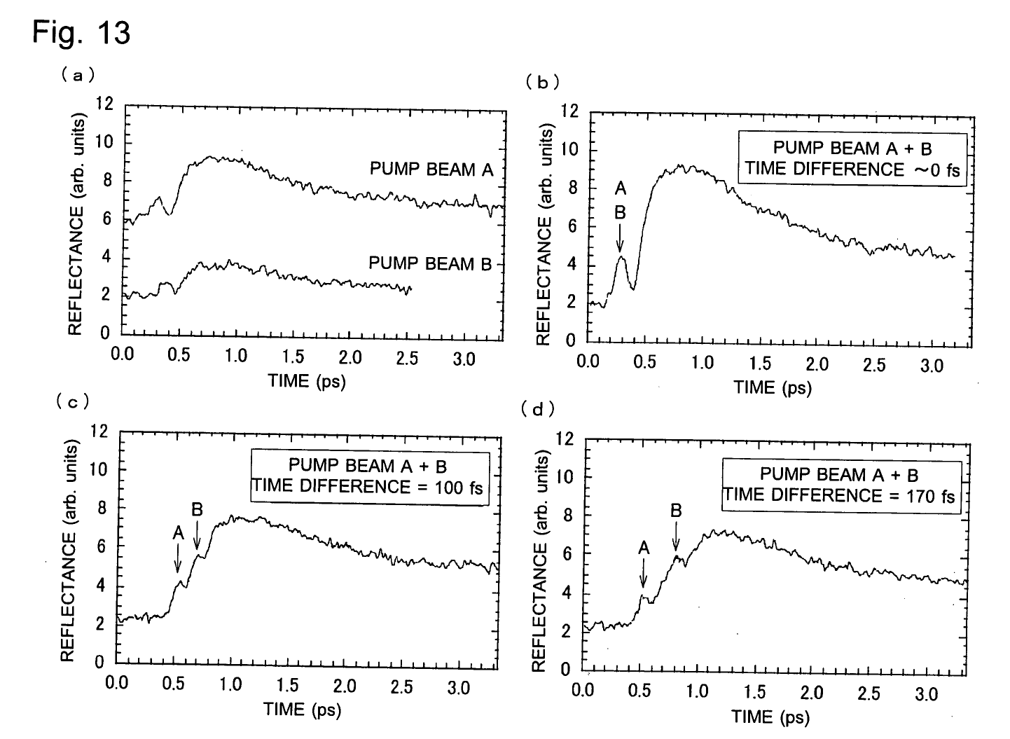

FIG. 13 is a set of graphs showing the temporal change of the reflectance observed in a measurement in which the number of the pump beam for excitation was increased to two pulses: pump beams A and B.

FIG. 13(a) shows the temporal change of the reflectance measured by separately using the two pump beams A and B. To investigate the effect of the complex excitation process caused by the two pump beams, the temporal change of the reflectance was measured for the following values of the time difference between the pump beams A and B: 0, 100 and 170 femtoseconds. The results of the measurement are shown in FIGS. 13(b) to (d).

As shown in FIGS. 13(b) to (d), any of the three settings of time-difference makes the pulse height larger than the simple sum of the waveforms shown in FIG. 13(a). This suggests that the effect of excitation becomes more remarkable as the surface is excited to a higher level at the moment of irradiation of the pump beam. This means that the excitation process of the ultra-short pulsed laser non-linearly increases.

The above-described measurement results show that the irradiation of the electromagnetic wave (light) in advance of the irradiation of the ultra-short pulsed laser excites the valence electrons to the conduction band through the multi-photon process or the (direct or indirect) absorption of the electromagnetic wave (light) whose photon energy exceeds the band gap. As a result, the surface presents in a more excited state and the irradiation of the ultra-short pulsed laser produces a more remarkable effect of excitation. Thus, it is possible to more effectively excite the surface by the irradiation of the ultra-short pulsed laser while suppressing the ablation.

### Embodiment 3

This section describes a method for manufacturing a p-channel metal-oxide-semiconductor field-effect transistor (MOSFET) using an example of modifying a crystalline phase into an amorphous phase, which is described in Embodiment 1. The present embodiment is also applicable to the manufacturing of an n-channel MOSFET.

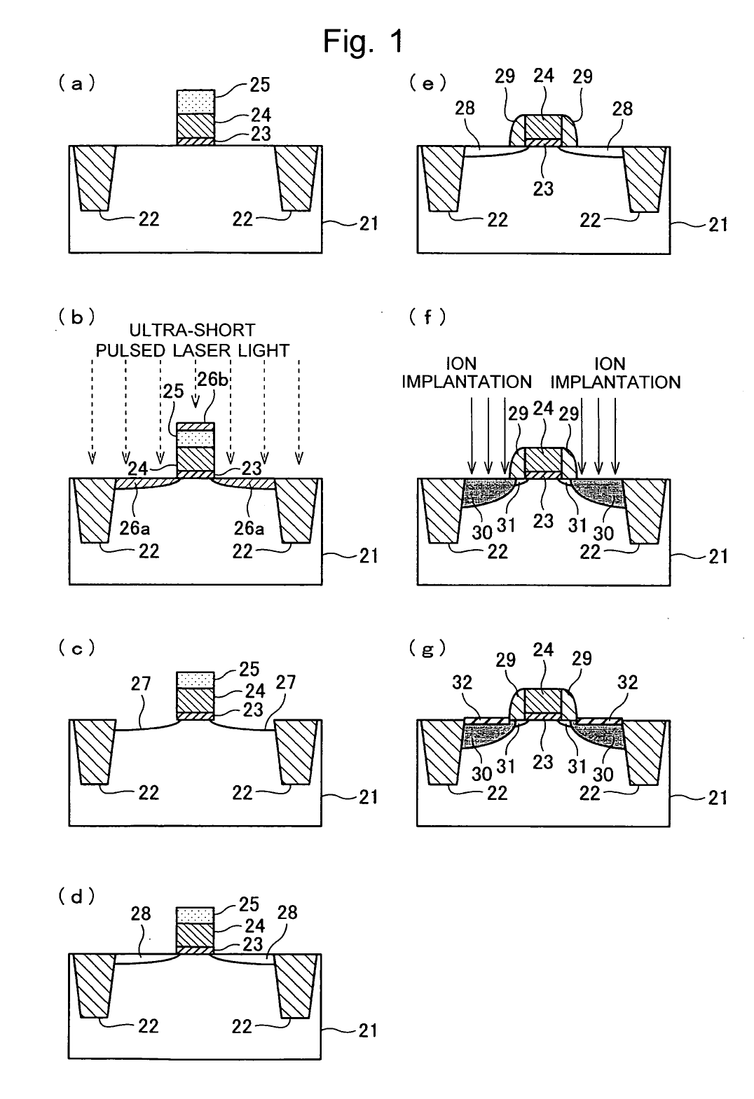

FIG. 1 is a set of sectional views of a semiconductor substrate illustrating the method for manufacturing a p-channel MOSFET in the present embodiment.

As shown in FIG. 1(a), device-separating insulation films 22 are formed in the semiconductor substrate 21 (e.g. silicon), on which the following three layers are formed: an insulating layer to be used as a gate insulation film (e.g. a high dielectric constant oxide film, such as Y₂O₃, La₂O₃, ZrO₂ or HfO₂); a gate electrode material layer (e.g. polycrystalline silicon or polycrystalline SiGe containing an impurity, a metallic material such as Pt, Ir, Ni or Co, or a conductive nitride such as TaN or WN); and an electrode protection layer (e.g. polysilicon, Al or some other metallic materials that are suitable for the reactive etching and well absorbs the ultra-short pulsed laser light). Subsequently, the patterning of the resist by photolithography and the reactive ion etching are performed to create a gate insulation film 23, a gate electrode 24 and an electrode protection film 25 on the semiconductor substrate 21. The region of the semiconductor substrate 21 at which the gate electrode 24 and the gate insulation film 23 are formed is the channel region.

Next, as shown in FIG. 1(b), the semiconductor substrate 21 is set on the sample stage 6 in the chamber 5 of the irradiation system 1, and an ultra-short pulsed laser light is cast onto the surface of the semiconductor substrate 21. For example, a titanium-sapphire laser light having a wavelength of 800 nm and a pulse width of 100 femtoseconds is cast onto the surface of the semiconductor substrate 21. In this operation, as shown in FIG. 5, the laser light should be cast onto the surface of the semiconductor substrate 21 at a laser fluence lower than the threshold that gives the maximum gradient of the ablation rate with respect to the laser fluence; the threshold is 400 mJ/cm² in the present embodiment. This setting suppresses the ablation on the surface of the semiconductor substrate 21.

The above process amorphizes only the surface region of the semiconductor substrate, as shown in FIGS. 3 and 4, for example. As shown in FIG. 1(b), the surfaces of the semiconductor substrate 21 and the electrode protection film 25 become the amorphous layers 26a and 26b, respectively.

Subsequently, the semiconductor substrate 21 is subjected to an etching process using reactive halogen plasma to selectively remove the amorphous layers 26a and 26b. As a result, recesses 27 are formed on the surface of semiconductor substrate 21, as shown in FIG. 1(c). The depth of the recesses 27 can be controlled within a range from a few to about 30 nm by changing the laser fluence of the ultra-short pulsed laser light used in FIG. 1(b).

Next, the semiconductor substrate 21 is transferred to a chemical vapor deposition (CVD) system, where the natural oxide film formed on its surface is removed. Immediately after this process, the recesses 27, from which the amorphous layers 26a were removed by the previous etching, are filled with a semiconductor layer containing a semiconductor impurity (i.e. boron, because the MOSFET in the present embodiment is p-type) to form semiconductor-embedded layers 28, as shown in FIG. 1(d). This process creates a source/drain (S/D) extension region having a depth of a few to about 30 nm in the vicinity of the gate insulation film 23.

Next, an insulation film is formed on the entire semiconductor substrate 21 to a level of the top of the gate electrode 24. Then, the film is made to be planate at the height of the gate electrode by chemical-mechanical polishing (CMP). As a result, the electrode protection film 25 is removed. Subsequently, a reactive ion etching is performed to create sidewalls 29 on the side of the gate electrode 24, as shown in FIG. 1(e). The sidewalls 29 later serves as a mask for protecting the S/D extension region when an ion-implanting process is performed to create a Deep diffusion layer.

Next, as shown in FIG. 1(f), boron ions are implanted only into the regions where p-channel type S/D regions are to be formed; the other region is masked with a photoresist. More specifically, the boron ions are implanted at an acceleration energy of 5 keV by a dose amount of 5×10¹⁵ ions/cm². After the implantation of the boron ions, an annealing treatment including a rapid heating/rapid cooling process using an infrared lamp or flash lamp is performed to create a Deep diffusion layer 30, as shown in FIG. 1(f). This layer becomes the main portion of the p-channel type S/D regions. A portion of each semiconductor-embedded layer 28 masked with the sidewall 29 becomes the S/D extension region 31, which is an ultra-shallow junction layer.

Finally, low-resistance ohmic-contact electrodes are created by developing silicide layers 32 on the Deep diffusion layer 30 through the creation of a film of high-melting point metal (e.g. Co or Ni) followed by a thermal process. Finally, a silicide process using chemicals is performed to remove the unreacted high-melting point metal remaining on the sidewalls 29 and the device-separating insulation films 22. Thus, a p-channel MOSFET with shallow S/D extension regions 31 having a depth of a few to 30 nm is obtained, as shown in FIG. 1(g).

In the above-described manufacturing method, the process of using the ultra-short pulsed laser irradiation for amorphizing the semiconductor substrate 21 was applied to the creation of the recesses 27 and the semiconductor-embedded layers 28. Part of the semiconductor-embedded layers 28 thus created finally remain as the S/D extension regions 31. Alternatively, it is possible to use a resist or similar mask so that a shallow recess for the S/D extension region and a deep recess for the Deep diffusion layer are created when the semiconductor substrate 21 is irradiated with the ultra-short pulsed laser, and to create the semiconductor-embedded layer in these recesses. In this case, the semiconductor-embedded layer formed in the deep recess can be used “as is” as the Deep diffusion layer, so that the ion-implanting process shown in FIG. 1(f) is unnecessary.

If the gate electrode 24 is made of polysilicon, it is possible to form another silicide layer also on the gate electrode 24.

As described thus far, the method according to the present method is a method for manufacturing a semiconductor device including:

a gate electrode 24 formed on a semiconductor substrate 21 via a gate insulating film 23; and

Deep diffusion layers 30 corresponding to an impurity-enriched source-side region and an impurity-enriched drain-side region, both formed on the semiconductor substrate 21 so that the two regions face each other across a channel region at which the gate electrode 24 is formed,

and the method includes:

an amorphous layer formation process in which amorphous layers 26a are created between the channel region and the impurity-enriched source-side region as well as between the channel region and the impurity-enriched drain-side region by casting a pulsed laser light having a pulse width within a range from 10 to 1000 femtoseconds;

a recess formation process for creating recesses 27 in the semiconductor substrate by selectively etching the amorphous layer; and

a source/drain extension region formation process for creating source/drain extension regions 31 by filling the recesses 27 with semiconductor layers 28 whose impurity concentration is higher than that of the semiconductor substrate.

In the MOSFET created by the manufacturing method according to the present embodiment, no second element resulting from ion implantation remains on the surface after the selective etching of the amorphous layer because the germanium ion implantation, which is used in conventional methods, is not performed in the amorphization of the surface of the semiconductor substrate. Even if the ion implantation uses the same element as that of the semiconductor substrate, the conventional methods cannot avoid the problem of an implantation defect remaining on the interface because the depth-directional range of the ions during the ion implantation is distributed. In contrast, according to the present embodiment, as shown in FIGS. 3 and 4, the depth of the amorphous phase is uniform, so that an interface suitable for epitaxial growth during the filling process can be created. An advantage also exists with respect to the lowering of the resistance of the S/D extension regions 31.

### Embodiment 4

This section describes a method for manufacturing a p-channel MOSFET using the technique of activating the impurity layer by an irradiation of an ultra-short pulsed laser light described in Examples 1-3. The present embodiment is also applicable to the manufacturing of an n-channel MOSFET.

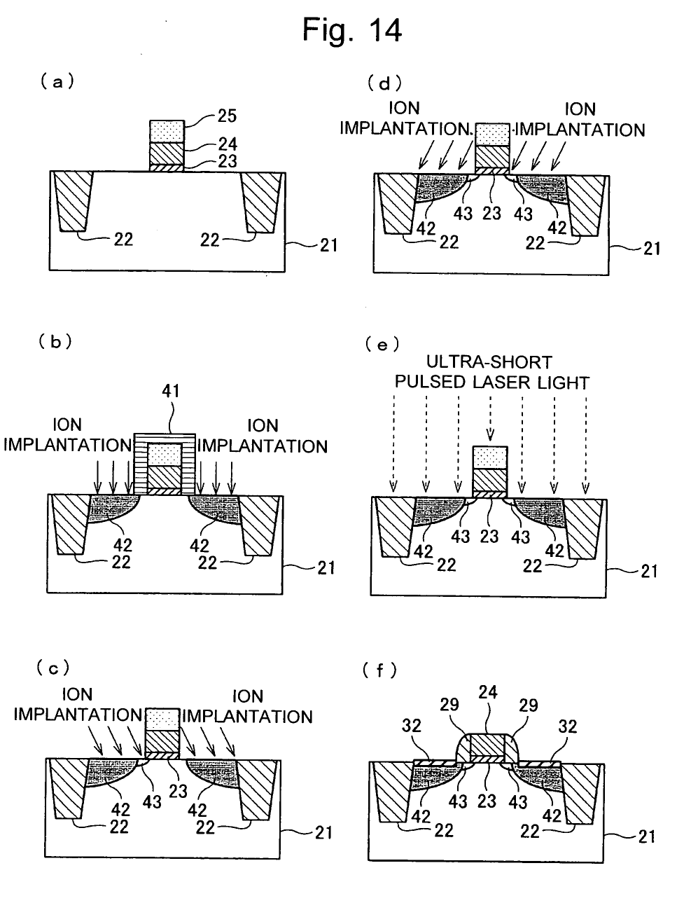

FIG. 14 is a set of sectional views of a semiconductor substrate illustrating the method for manufacturing a p-channel MOSFET in the present embodiment.

As in the case of Embodiment 3, a gate insulation film 23, first a gate electrode 24, an electrode protection film 25 are formed on the semiconductor substrate 21 in which device-separating insulation films 22 are formed (see FIG. 14(a)).

Next, as shown in FIG. 14(b), a region surrounding the gate electrode is masked with a resist; this region corresponds to the S/D extension regions to be created later. Then, boron ions are implanted into the surface of the semiconductor substrate 21. For example, these ions are implanted at an acceleration energy of 5 keV by a dose amount of 5×10¹⁵ ions/cm². After the implantation of the boron ions, an annealing treatment including a rapid heating/rapid cooling process using an infrared lamp or flash lamp is performed to create a Deep diffusion layer 30, as shown in FIG. 14(b). This layer is the main portion of the p-channel S/D region. Before this annealing process, the resist 41 is removed by an ashing process.

Subsequently, the portion of the semiconductor substrate 21 other than the p-channel region is masked with a photoresist. Then, as shown in FIGS. 14(c) and (d), using the gate insulation film 23, the gate electrode 24 and the electrode protection film 25 as a mask for the p-channel region, boron ions are implanted to create boron ion-implanted layers 43 in a self-aligned manner. For example, the ions are implanted at an acceleration energy of 0.2 keV by a dose amount of 4×10¹⁵ ions/cm². To prevent shadowing by the gate insulation film 23, the gate electrode 24 and the electrode protection film 25, the ions are implanted from both the source and drain sides at an incident angle of about 60 degrees with respect to the surface of the semiconductor substrate 21. Thus, the S/D extension regions 43 having a depth of about 5 nm from the surface of the semiconductor substrate are obtained.

Before the implantation of the boron ions, it is possible to perform a pre-amorphization in which germanium ions are implanted from both the source and drain sides at an incident angle of about 60 degrees with respect to the surface of the semiconductor substrate 21 at an acceleration energy of 5 keV by a dose amount of 1×10¹⁵ ions/cm². This process amorphizes the semiconductor within the region from the surface of the semiconductor substrate 21 to a depth of about 5 nm, which becomes an amorphous layer. Simultaneously, the boron ions introduced into the semiconductor substrate 21 forms the boron-ion implanted layers 43 having a depth of about 5 nm from the surface of the semiconductor substrate 21. The pre-amorphization suppresses the channeling during the ion-implanting process and the enhanced diffusion during the activation process, thus enabling a high precision control of the distribution of the impurity.

Next, using the irradiation system 1, an ultra-short pulsed laser light (e.g. a titanium-sapphire laser light having a wavelength of 800 nm and a pulse width of 100 femtoseconds) is cast onto the surface of the semiconductor substrate 21. In this operation, the condition of the laser fluence, the number of pulse shots and the state of polarization can be optimized to lower the sheet resistance on the basis of the results of the experiments performed using the TEG, as shown in FIGS. 8 to 10. As a result, the sheet resistance at the S/D extension regions can be further lowered to a level of 1 kΩ/sq. or even lower.

During the process of casting the ultra-short pulsed laser light, it is preferable to maintain the semiconductor substrate 21 at a temperature (e.g. about 500 degrees Celsius or lower) that does not significantly affect the diffusion of the dopant (i.e. boron) to the depth direction and the lateral direction parallel to the surface of the semiconductor substrate 21. Particularly, casting the ultra-short pulsed laser light onto the semiconductor substrate 21 maintained at about 500 degrees Celsius can reduce the junction leakage.

The presence of the electrode protection film 25 on the gate electrode 24 has the effect of preventing the gate electrode 24 from being damaged due to ablation or other reasons when the ultra-short pulsed laser light is cast onto the semiconductor substrate 21.

The ultra-short pulsed laser light cast onto the semiconductor substrate 21 electrically activates the boron-implanted layers 43, which have an implantation depth of about 5 nm from the surface of the semiconductor substrate 21. These layers become the S/D extension regions where a shallow p-n junction is formed.

Next, an insulation film is formed on the entire semiconductor substrate 21 to the height of the gate electrode 24. Then, the film is made to be planate at the height of the gate electrode 24 by the CMP treatment. As a result, the electrode protection film 25 is removed. Subsequently, a reactive ion etching is performed to create sidewalls 29 on the side of the gate electrode 24, as shown in FIG. 14(f).

Finally, low-resistance ohmic-contact electrodes are created by developing silicide layers 32 on the Deep diffusion layer 42 of the S/D regions through the creation of a film of high-melting point metal (e.g. Co or Ni) followed by a thermal process. Then, a silicide process using chemicals is performed to remove the unreacted high-melting point metal remaining on the sidewalls 29 and the device-separating insulation films 22. Thus, a p-type MOSFET with very shallow S/D extension regions having a depth of about 5 nm is obtained, as shown in FIG. 14(f).

As described thus far, the method according to the present method is a method for manufacturing a semiconductor device including:

a gate electrode 24 formed on a semiconductor substrate 21 via a gate insulating film 23; and

Deep diffusion regions 42 corresponding to an impurity-enriched source-side region and an impurity-enriched drain-side region, both formed on the semiconductor substrate 21 so that the two region face each other across a channel region at which the gate electrode 24 is formed,

and the method includes:

an impurity layer formation process in which impurity layers 43 are formed by implanting an impurity element to a predetermined depth between the channel region and the impurity-enriched source-side region as well as between the channel region and the impurity-enriched drain-side region; and

an impurity layer activation process for activating the impurity layers by the impurity activation method described in Embodiment 2. This method can lower the sheet resistance of the activated impurity layer to 1 kΩ/sq or lower, for example.

In Embodiments 3 and 4, before the irradiation of the ultra-short pulsed laser light, the electronic state of the surface may be excited beforehand by casting a light of a wavelength having a photon energy higher than the band gap of the substrate material, as explained in Embodiment 2. This also makes it possible to modify a crystalline phase into an amorphous phase or activate an impurity layer using an ultra-short pulsed laser light while suppressing the ablation.

The present invention is not restricted by the embodiments described above and can be embodied in various forms. Any technical elements disclosed in different embodiments can be combined to create a new embodiment, and such an embodiment is also included in the technical scope of the present invention.

### INDUSTRIAL APPLICABILITY

The surface modification method for a solid sample according to the present invention provides a modified layer having a uniform interface free from other ions. This method can be used, for example, to create an amorphous layer in the process of creating an ultra-shallow junction layer of a semiconductor device. The impurity activation method according to the present invention has the effect of lowering the sheet resistance and hence can be applied to the manufacturing of semiconductor devices.

1. A surface modification method for a solid sample, comprising a step of irradiating the solid sample with a pulsed laser light having a pulse width within a range from 10 to 1000 femtoseconds so as to modify only a surface layer of the solid sample from a crystalline phase to an amorphous phase or from an amorphous phase to a crystalline phase.

2. The surface modification method for a solid sample according to claim 1, wherein
in a relationship between an ablation rate of the solid sample due to an irradiation of the pulsed laser light and a laser fluence of the pulsed laser light, a laser fluence value that gives a maximal value of a gradient of the ablation rate with respect to the laser fluence is identified as a threshold laser fluence; and
the solid sample is irradiated with the pulsed laser light with a laser fluence equal to or lower than the threshold laser fluence.

3. The surface modification method for a solid sample according to claim 1, wherein the solid sample is made of a semiconductor material, and the semiconductor material is irradiated with an electromagnetic wave to excite valence electrons to a conduction band before an irradiation of the pulsed laser light.

4. The surface modification method for a solid sample according to claim 3, wherein the aforementioned electromagnetic wave has a wavelength corresponding to an energy level higher than a band gap within the semiconductor material.

5. The surface modification method for a solid sample according to claim 1, wherein the pulsed laser light is a circularly polarized light.

6. An impurity activation method, wherein:
an impurity layer whose impurity concentration is higher than that of a semiconductor substrate is formed on the semiconductor substrate; and
the impurity layer is irradiated with a pulsed laser light having a pulse width within a range from 10 to 1000 femtoseconds in order to activate the impurity layer,
where a sheet resistance of the impurity layer after an irradiation of the pulsed laser light is controlled by changing irradiation conditions including the pulse width, a laser fluence and a number of pulse shots of the pulsed laser light.

7. The impurity activation method according to claim 6, wherein:
in a relationship between the pulse width of the pulsed laser light and the sheet resistance of the impurity layer after the irradiation of the pulsed laser light, a gradient of the sheet resistance with respect to the pulse width changes at a specific threshold pulse width;
the gradient within a range below the threshold pulse width is larger than that within a range above the threshold pulse width; and
the impurity layer is irradiated with the pulsed laser light with a pulse width equal to or smaller than the threshold pulse width.

8. The impurity activation method according to claim 6, wherein:
in a relationship between the laser fluence of the pulsed laser light and the sheet resistance of the impurity layer after the irradiation of the pulsed laser light, the sheet resistance takes a minimum value at the laser fluence; and
the impurity layer is irradiated with the pulsed laser light at a laser fluence that gives a substantially minimal value of the sheet resistance.

9. The impurity activation method according to claim 6, wherein:
in a relationship between a number of pulse shots of the pulsed laser light and the sheet resistance of the impurity layer after the irradiation of the pulsed laser light, the sheet resistance takes a minimum value at the number of pulse shots; and
the impurity layer is irradiated with a pulsed laser light at a number of pulse shots that gives a substantially minimal value of the sheet resistance.

10. The impurity activation method according claim 6, wherein the impurity layer is irradiated with an electromagnetic wave to excite valence electrons to a conduction band before the irradiation of the pulsed laser light.

11. The impurity activation method according to claim 10, wherein the aforementioned electromagnetic wave has a wavelength corresponding to an energy level higher than a band gap within the semiconductor substrate.

12. The impurity activation method according to claim 6, wherein the pulsed laser light is a circularly polarized light.

13. The impurity activation method according to claim 6, wherein, when or before the impurity layer is formed, a semiconductor atom is added to or introduced into a region where the impurity layer is to be formed and the region is amorphized.

14. The impurity activation method according to claim 13, wherein the semiconductor substrate is made of silicon and the semiconductor atom is silicon or germanium.

15. A method for manufacturing a semiconductor device, wherein the device includes:
a gate electrode formed on a semiconductor substrate via a gate insulating film; and
an impurity-enriched source-side region and an impurity-enriched drain-side region, both formed on the semiconductor substrate so that the two regions face each other across a channel region at which the gate electrode is formed,
and the method includes:
an amorphous layer formation process in which an amorphous layer is created between the channel region and the impurity-enriched source-side region as well as between the channel region and the impurity-enriched drain-side region by casting a pulsed laser light having a pulse width within a range from 10 to 1000 femtoseconds;
a recess formation process for creating recesses in the semiconductor substrate by selectively etching the amorphous layer; and
a source/drain extension region formation process for creating source/drain extension regions by filling the recesses with semiconductor layers whose impurity concentration is higher than that of the semiconductor substrate.

16. A method for manufacturing the semiconductor device, wherein the device includes:
a gate electrode formed on a semiconductor substrate via a gate insulating film; and
an impurity-enriched source-side region and an impurity-enriched drain-side region, both formed on the semiconductor substrate so that the two regions face each other across a channel region at which the gate electrode is formed,
and the method includes:
an impurity layer formation process in which impurity layers are formed by implanting an impurity element into a predetermined depth between the channel region and the impurity-enriched source-side region as well as between the channel region and the impurity-enriched drain-side region; and
an impurity layer activation process for activating the impurity layers by the impurity activation method according claim 6.
